(19) United States
(12) Patent Application Publication
(10) Pub. No.: US 2024/0251685 A1
(43) Pub. Date: Jul. 25, 2024

(54) MAGNETIC MEMORY DEVICES USING SPIN CURRENT AND ELECTRONIC APPARATUSES INCLUDING THE MAGNETIC MEMORY DEVICES

(71) Applicant: Samsung Electronics Co., Ltd., Suwon-si (KR)

(72) Inventors: Kwangseok KIM, Suwon-si (KR); Naoki HASE, Hwaseong-si (KR); Jeongchun RYU, Suwon-si (KR); Jungsik PARK, Suwon-si (KR)

(73) Assignee: Samsung Electronics Co., Ltd., Suwon-si (KR)

(21) Appl. No.: 18/492,181

(22) Filed: Oct. 23, 2023

(30) Foreign Application Priority Data
Jan. 20, 2023 (KR) 10-2023-0009034

(51) Int. Cl. H10N 50/20; H10B 61/00; H10N 50/85

(52) U.S. Cl. CPC H10N 50/20; H10B 61/00; H10N 50/85

(57) ABSTRACT

A magnetic memory device may include a spin current channel layer, a wiring crossing the spin current channel layer, and an MTJ layer at an intersection of the spin current channel layer and the wiring. The spin current channel layer may include an MgO-based layer and a beta (β)-phase tungsten (W) layer on the MgO-based layer. The beta (β)-phase tungsten (W) layer may be in contact with the MTJ layer.

### CROSS-REFERENCE TO RELATED APPLICATION

This application is based on and claims priority under 35 U.S.C. § 119 to Korean Patent Application No. 10-2023-0009034, filed on Jan. 20, 2023, in the Korean Intellectual Property Office, the disclosure of which is incorporated by reference herein in its entirety.

### BACKGROUND

### 1. Field

The disclosure relates to memory devices, and more particularly, to magnetic memory devices using a spin current and electronic apparatuses including the magnetic memory devices.

### 2. Description of the Related Art

A magnetic memory device writes or reads information using a tunneling magnetoresistance (TMR) phenomenon.

When magnetic moment directions of two magnetic layers included in a magnetic tunnel junction (MTJ) of the magnetic memory device are parallel to each other, the magnetic memory device has a low resistance, and when the two layers are antiparallel to each other, the magnetic memory device has a high resistance.

The MTJ includes the two magnetic layers, that is, a pinned layer in which a direction of a magnetic moment is fixed and is also referred to as a fixed layer and a free layer in which a direction of a magnetic moment may be switched.

A magnetic memory device using spin transfer torque for a write operation to determine the direction of the free layer is referred to as STT-magnetoresistive random-access memory (MRAM), and a magnetic memory device using spin orbit torque is referred to as SOT-MRAM.

The STT-MRAM is a technology applied to an embedded memory, and read and write operations are performed using a current flowing through the MTJ.

The SOT-MRAM includes a three-terminal structure in which a free layer is switched by a current flowing in a spin orbit torque (SOT) layer formed under the MTJ.

Compared to the STT-MRAM, the SOT-MRAM enables fast operation (<1 nsec) of less than 1 nanosecond, and because a write path and a read path are separated from each other, a write bias is not directly applied to the tunnel barrier layer of MTJ, thereby improving endurance.

### SUMMARY

Provided are magnetic memory devices using a spin current capable of preventing and/or minimizing SOT layer damage that may occur in a manufacturing process.

Provided are magnetic memory devices using a spin current capable of enhancing perpendicular magnetic anisotropy with respect to a free layer of an MTJ layer.

Provided are magnetic memory devices using a spin current capable of lowering an operating current density.

Provided are magnetic memory devices using a spin current capable of increasing yield.

Provided are electronic apparatuses including such a magnetic memory device.

Additional aspects will be set forth in part in the description which follows and, in part, will be apparent from the description, or may be learned by practice of the presented embodiments of the disclosure.

According to an embodiment, a magnetic memory device may use a spin current. The magnetic memory device may include a spin current channel layer, a wiring crossing the spin current channel layer, and a magnetic tunnel junction (MTJ) layer at an intersection of the spin current channel layer with the wiring. The spin current channel layer may include an MgO-based layer and a beta (β)-phase tungsten layer on the MgO-based layer. The beta (β)-phase tungsten layer may be in contact with the MTJ layer.

In some embodiments, the MgO-based layer may be a single layer including an MgO layer.

In some embodiments, the MgO-based layer may include a first layer and a second layer on the first layer. The second layer may be in contact with the beta-phase tungsten layer.

In some embodiments, the second layer may include an MgO layer.

In some embodiments, the first layer may be a single layer including a metal of one component.

In some embodiments, the first layer may include a two-component material layer and the two-component material layer may include a metal component and a non-metal component. In some embodiments, the two-component material layer may include one of a metal oxide and a metal nitride.

In some embodiments, the first layer may include an alloy.

In some embodiments, the first layer may include a three-component material layer and the three-component material layer may include two different metals and one non-metal component.

In some embodiments, the first layer may include a first material layer and a second material layer on the first material layer. In some embodiments, the first material layer may include one of Ta and TaB, and the second material layer may include CoFeB. In some embodiments, a thickness of the beta-phase tungsten layer may be in a range from about 5.5 nm to about 8.0 nm.

In some embodiments, the magnetic memory device may further include a plurality of the spin current channel layers spaced apart from each other, a plurality of the wirings spaced apart from each other, and a plurality of MTJ layers at intersections of the plurality of spin current channel layers with the plurality of wirings.

According to an embodiment, a magnetic memory device may use a spin current. The magnetic memory device may include a spin current channel layer, a wiring crossing the spin current channel layer, and an MTJ layer at an intersection of the spin current channel layer with the wiring. The spin current channel layer may include a first layer and a second layer on the first layer. The first layer may include a metal. The second layer may have a spin hall angle (SHA) in a range from about 0.3 to about 0.5.

In some embodiments, the first layer may include one of a TaN layer and an NiO layer.

In some embodiments, the magnetic memory device may include a first material layer contacting the first layer.

In some embodiments, the first material layer may include at least one of a single-layer metal layer, an alloy layer, and a three-component material layer.

According to an embodiment, an electronic apparatus may include any one of the magnetic memory devices described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a first magnetic memory device according to an embodiment;

FIG. 2 is a cross-sectional view illustrating a second magnetic memory device according to an embodiment;

FIG. 3 is a plan view illustrating a unit magnetic memory device according to an embodiment;

FIG. 4 is a plan view illustrating a SOT-MRAM array including unit magnetic memory devices of FIG. 3;

FIG. 5 is a graph showing experimental results for a thickness of an SOT layer (e.g., a tungsten layer) formed on an MgO-based layer of a magnetic memory device according to an embodiment;

FIG. 6 shows a table summarizing layer structures, layer configurations, and formation conditions of the SOT layer and the MTJ layer sequentially formed in first and second experiments to obtain the experimental results of FIG. 5;

FIGS. 7A and 7B are graphs showing results of an experiment conducted to confirm perpendicular magnetic anisotropy of a free layer of an MTJ layer formed on an SOT layer (e.g., a tungsten layer) of a magnetic memory device according to an embodiment;

FIG. 8 shows a table summarizing layer structures, layer configurations, and formation conditions of comparative and reference devices used in experiments conducted to obtain the experimental results of FIGS. 7A and 7B;

FIG. 9 is a diagram illustrating a first electronic apparatus according to an embodiment;

FIG. 10 is a block diagram illustrating a second electronic apparatus according to an embodiment;

FIG. 11 is a block diagram illustrating a third electronic apparatus according to an embodiment;

FIG. 12 is a block diagram showing a schematic configuration of a fourth electronic apparatus according to an embodiment; and

FIG. 13 is a diagram schematically illustrating a fifth electronic apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of a, b, and c” may be understood to include “only a,” “only b,” “only c,” “a and b,” “a and c,” “b and c,” or “a, b, and c”.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, a magnetic memory device using a spin current according to an embodiment and an electronic apparatus including the magnetic memory device will be described in detail with reference to the accompanying drawings. The drawings are not to scale, and thicknesses of layers and regions may be exaggerated for clarification of the specification. The following embodiments described below are merely illustrative, and various modifications may be possible from the embodiments of the disclosure. When an element or layer is referred to as being “on” or “above” another element or layer, the element or layer may be directly on another element or layer or intervening elements or layers. In the description below, like reference numerals in each drawing denote like members.

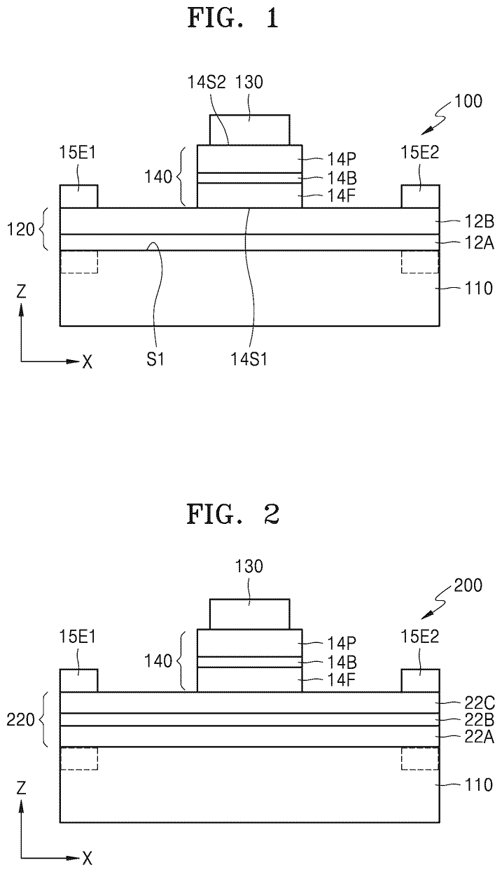

FIG. 1 shows a first magnetic memory device 100 including a spin orbit torque (SOT) layer according to an embodiment. In some embodiments, the first magnetic memory device 100 may be a memory device of a minimum unit of SOT-magnetoresistive random-access memory (MRAM). Accordingly, the first magnetic memory device 100 may be expressed as a unit memory device or a unit memory cell.

Referring to FIG. 1, the first magnetic memory device 100 includes a lower layer 110, a first spin current channel layer 120, and a data storage layer 140 sequentially stacked. The lower layer 110 may be expressed as a substrate or a substrate layer. In some embodiments, the lower layer 110 may be an insulating layer or an interlayer insulating layer or include such an insulating layer. In some embodiments, the lower layer 110 may include an oxide layer or a nitride layer. For example, the lower layer 110 may include a silicon oxide layer (e.g., a SiO₂ layer). The first spin current channel layer 120 is formed on the one surface S1 of the lower layer 110. In some embodiments, the one surface S1 of the lower layer 110 may be an upper surface, but the one surface S1 may be a lower surface, a side surface, or an inclined surface depending on a point of view. The first spin current channel layer 120 may be a material layer through which a spin current flows in at least a partial region or a material layer through which a current including a spin current flows in at least a partial region. In some embodiments, a spin current may flow through the entire first spin current channel layer 120. In some embodiments, a spin current may flow in a region of the first spin current channel layer 120 corresponding to the data storage layer 140. For example, a spin current may flow in a region of the first spin current channel layer 120 in contact with the data storage layer 140. The spin current may include a spin-up current and a spin-down current. In some embodiments, the first spin current channel layer 120 may be an SOT layer. Because the first spin current channel layer 120 is a layer through which a current is transmitted, the first spin current channel layer 120 may be expressed as a wiring or wiring layer.

In some embodiments, the first spin current channel layer 120 may include a first layer 12A and a second layer 12B sequentially stacked on the lower layer 110. In some embodiments, a thickness of the first layer 12A and a thickness of the second layer 12B may be different or the same. The first layer 12A is formed on the one surface S1 of the lower layer 110 and may directly contact the one surface S1. In some embodiments, an entire portion of the one surface S1 of the lower layer 110 corresponding to the first layer 12A may be covered with the first layer 12A. In some embodiments, when electrodes (layer) are provided in the lower layer 110 (illustrated as a box indicated by dotted lines), the first layer 12A may be provided to contact the electrodes and the one surface S1 between the electrodes. In some embodiments, the first layer 12A may be a single layer. In some embodiments, the first layer 12A may have a first thickness. In some embodiments, the first thickness may be 3 nm or less or 1 nm or less, but is not limited thereto. In some embodiments, the first layer 12A may be or include a material layer having a first surface energy. For example, the first layer 12A may include oxide or nitride including a first metal, but is not limited thereto. In some embodiments, the first metal may include any one of magnesium (Mg), tantalum (Ta), and nickel (Ni). For example, the first layer 12A may include an MgO layer, a TaN layer, or an NiO layer. In some embodiments, the first thickness may vary depending on a material used as the first layer 12A, but may not be the case. In some embodiments, the first layer 12A may not include silicon oxide (e.g., SiO₂).

The second layer 12B may be formed to cover an entire upper surface of the first layer 12A. The upper surface of the first layer 12A may be substantially parallel to a plane (X-Y plane) formed by an X axis and a Y axis, or may be substantially parallel to the one surface S1 of the lower layer 110.

In some embodiments, the second layer 12B may be or include a material layer showing a spin Hall effect. In some embodiments, the second layer 12B may include a material layer having a first value of a spin hole angle (SHA), which is a rate at which a charge current is converted into a spin current. In some embodiments, the first value may be greater than about 0.3 and less than about 1.0, for example, the first value may be in a range from 0.3 to 0.5, 0.3 to 0.6, or 0.4 to 0.6, but is not limited thereto. That the first value is about 0.3 means that 30% of a charge current supplied to the second layer 12B is converted into spin current.

In some embodiments, the second layer 12B may have a second thickness greater than the first thickness. In some embodiments, the second thickness may be about 10 nm or less, for example, in a range from 5 nm to 10 nm, 5 nm to 9 nm, 5 nm to 8 nm, 5.5 nm to 7 nm, 5.5 nm to 7.5 nm, 6 nm to 7 nm, 6 nm to 8 nm, 4.5 nm to 6nm, or 4.5nm to 8nm, but is not limited thereto. In some embodiments, the second layer 12B may be or include a material layer having a second surface energy greater than the first surface energy. In some embodiments, the second layer 12B may be or include a heavy metal layer having relatively high spin-orbit coupling, but is not limited thereto. For example, the second layer 12B may include a tungsten (W) layer or a platinum (Pt) layer. In some embodiments, when the second layer 12B includes a tungsten layer, the second layer 12B may include a β-phase tungsten layer. In some embodiments, a surface roughness of the second layer 12B may be in a range from about 0.5 Å to about 6 Å, about 1 Å to about 5 Å, or about 4.5 Å to about 5.5 Å as a root mean square (RMS) roughness. In some embodiments, the second layer 12B may be deposited by using a method such as Chemical Vapor Deposition (CVD) method, a Physical Vapor Deposition (PVD) method, or a sputtering method, but is not limited to this method.

First and second electrodes 15E1 and 15E2 are provided to be spaced apart from each other on the second layer 12B. The first and second electrodes 15E1 and 15E2 may be expressed as first and second electrode layers 15E1 and 15E2. The first electrode 15E1 may contact one end of the second layer 12B, and the second electrode 15E2 may contact the other end of the second layer 12B. In some embodiments, the second layer 12B itself may be an electrode layer. For example, a portion of the second layer 12B contacting the first and second electrodes 15E1 and 15E2 may be used as an electrode (layer). In this case, the first and second electrodes 15E1 and 15E2 may be omitted.

In some embodiments, the first and second electrodes 15E1 and 15E2 may be provided under the first spin current channel layer 120 as indicated by dotted line boxes. For example, the first and second electrodes 15E1 and 15E2 may be buried in the lower layer 110 so that a surface of each of the first and second electrodes 15E1 and 15E2 is exposed, and the exposed surface of the first and second electrodes 15E1 and 15E2 may contact the first layer 12A of the current channel layer 120. In some embodiments, the first and second electrodes 15E1 and 15E2 may be provided under the first spin current channel layer 120 to directly contact the first layer 12A. In this example, a conductive member (e.g., a conductive layer) may further be provided between the first layer 12A and the first and second electrodes 15E1 and 15E2.

The data storage layer 140 is provided between the first spin current channel layer 120 and a third electrode 130. The third electrode 130 may also be expressed as a third electrode layer 130. The data storage layer 140 is formed on the first spin current channel layer 120 between the first and second electrodes 15E1 and 15E2 and does not contact the first and second electrodes 15E1 and 15E2. The entire data storage layer 140 may be provided on one surface (e.g., upper surface) of the second layer 12B of the first spin current channel layer 120. In some embodiments, the data storage layer 140 may be a magnetic tunnel junction (MTJ) layer.

The data storage layer 140 may include a first layer 14F, a second layer 14B, and a third layer 14P sequentially stacked from the first spin current channel layer 120 toward the third electrode 130. In some embodiments, sizes of the first to third layers 14F, 14B, and 14P may be equal to each other. Thicknesses of the first to third layers 14F, 14B, and 14P may be different from each other, but some may be the same. For example, the first layer 14F and the third layer 14P may have the same thickness or thicknesses of the first layer 14F and the third layer 14P may not be the same.

A bottom surface of the first layer 14F that directly contacts the first spin current channel layer 120 may correspond to a first surface 14S1 of the data storage layer 140. An upper surface of the third layer 14P that directly contacts the third electrode 130 may correspond to a second surface 14S2 of the data storage layer 140.

The first layer 14F and/or the third layer 14P may have a single layer or a layer structure including a plurality of single layers, that is, a multi-layer structure. A material of the first and third layers 14F and 14P may be different from that of the second layer 14B. In some embodiments, the first and third layers 14F and 14P may be or include magnetic layers. For example, the first layer 14F may include a ferromagnetic layer, for example, a CoFeB20 (CFB20) layer, but is not limited thereto. For example, the third layer 14P may include a ferromagnetic layer. In some embodiments, the third layer 14P may be a single-layer or may have a multi-layer structure. For example, the third layer 14P may include a CFB₃₀ layer, a Ta layer, and a Ru layer sequentially stacked.

The third layer 14P may be a pinned layer, a magnetic moment of which is fixed or substantially fixed in the first direction. The first layer 14F may be a free layer in which a magnetic moment may be rotated or switched in a first direction or a second direction by an action applied from the outside. The second direction may be opposite to the first direction. The first and second directions may be perpendicular to the first spin current channel layer 120 and/or the third electrode 130. That is, the first and third layers 14F and 14P may have perpendicular magnetic anisotropy (PMA).

In some embodiments, the action applied from the outside may be a magnetic field applied from the outside of the data storage layer 140 or a spin current transmitted through the first spin current channel layer 120.

When the magnetic moment of the first layer 14F and the magnetic moment of the third layer 14P are parallel or substantially parallel to each other in the same direction, the data storage layer 140 may be in a first state in which an electrical resistance is relatively low. Conversely, when the direction of the magnetic moment of the first layer 14F and the direction of the magnetic moment of the third layer 14P are opposite to each other, the data storage layer 140 may be in a second state in which the electrical resistance is greater than the first state. One of the first and second states may be regarded as writing data “1”, and the other may be regarded as writing data “0”.

The second layer 14B is a barrier layer, that is, a tunnel barrier, and may be an insulating layer or include such an insulating layer. In some embodiments, the insulating layer may include a magnesium oxide (e.g., MgO) layer, a boron nitride (BN) layer, or an aluminum oxide layer, but is not limited thereto.

The third electrode 130 provided on the data storage layer 140 may be shared by a plurality of the data storage layers 140 spaced apart from each other, and may be a wiring or a wiring layer. If the first spin current channel layer 120 is referred to as a first wire, the third electrode 130 may be referred to as a second wire.

FIG. 2 shows a second magnetic memory device 200 using a spin current according to an embodiment. Only parts different from the first magnetic memory device 100 of FIG. 1 will be described.

Referring to FIG. 2, the second magnetic memory device 200 may include a second spin current channel layer 220 in the position of the first spin current channel layer 120 of the first magnetic memory device 100. The second spin current channel layer 220 includes sequentially stacked first to third layers 22A to 22C. In a direction perpendicular to the one surface S1 of the lower layer 110 (e.g., in a Z-axis direction), the first layer 22A has a first thickness. The second layer 22B has a second thickness in a direction perpendicular to the one surface S1. The third layer 22C has a third thickness in a direction perpendicular to the one surface S1. The first to third thicknesses may be different from each other, but some may be the same. For example, the second thickness may be less than the first and third thicknesses. In some embodiments, the first and third thicknesses may be equal to each other, but may be different from each other.

In some embodiments, the role, layer structure, and material of the third layer 22C may be the same as that of the second layer 12B of the first spin current channel layer 120 of the first magnetic memory device 100.

In some embodiments, the role, layer structure, and material of the second layer 22B may be the same as that of the first layer 12A of the first magnetic memory device 100.

In some embodiments, the first layer 22A may be a single layer or may include a multi-layer structure. In some embodiments, the first layer 22A may be a material layer including a metal. In some embodiments, the second layer 22B may include a material layer including a metal and other components. In some embodiments, the first layer 22A may be an one-component first material layer including a single metal. In some embodiments, the first layer 22A may be a two-component second material layer in which one component is a single metal. In this case, the other one of the two components of the two-component second material layer may not be a metal. In some embodiments, the first layer 22A may be a two-component third material layer including two different types of metals. In some embodiments, the first layer 22A may be a three-component fourth material layer in which two components are metals of different types, and the other one of the three components of the three-component fourth material layer may not be a metal. In some embodiments, the first layer 22A may be a material layer of three or more components including a metal.

In some embodiments, the first material layer may include one of Cr, Co, Ni, Tb, Pt, and Ta, but is not limited thereto.

In some embodiments, the second material layer may include a metal-including nitride, a metal-including oxide, or a metal-including boride. For example, the second material layer may include one of TaN, NiO, and TaB, but is not limited thereto.

In some embodiments, the third material layer may be an alloy layer, and may include, for example, CoFe, but is not limited thereto.

In some embodiments, the fourth material layer may include CoFeB, but is not limited thereto.

In some embodiments, the first layer 22A may include a single layer including at least one of the first to fourth material layers or a multi-layer structure.

When the first layer 22A is a single layer, for example, the first layer 22A may be a single layer including one of the first to third material layers, but is not limited thereto.

When the first layer 22A has a multi-layer structure, for example, the first layer 22A may have a multi-layer structure including the first material layer and the fourth material layer or. a multi-layer structure including the second material layer and the fourth material layer. For example, the first layer 22A may include a layer structure including a Ta layer and a CoFeB layer sequentially stacked on the lower layer 110 or a layer structure including a TaB layer and a CoFeB layer sequentially stacked on the lower layer 110.

Except for the second spin current channel layer 220, the remaining layer structures and layer configurations of the second magnetic memory device 200 may be the same as those of the first magnetic memory device 100.

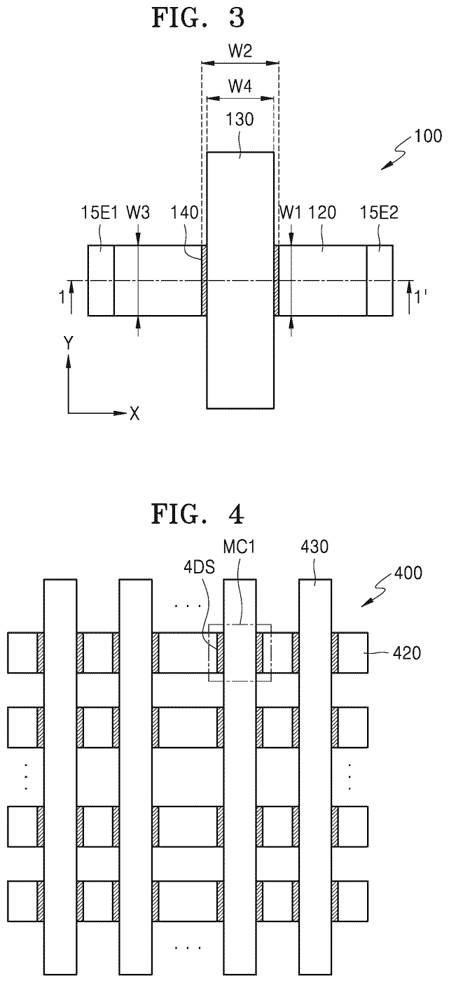

FIG. 3 is a plan view of the first magnetic memory device 100. FIG. 1 is a cross-sectional view taken along line 1-1′ of FIG. 3. FIG. 3 may be a plan view of the second magnetic memory device 200, and FIG. 2 may be a cross-sectional view of FIG. 1 cut in a 1-1′ direction.

Referring to FIGS. 3 and 1 together, the data storage layer 140 is formed between the first spin current channel layer 120 and the third electrode 130 that vertically cross or substantially vertically cross each other.

The data storage layer 140 may have a first width W1 in a direction (Y-axis direction) perpendicular to a length direction (X-axis direction) of the first spin current channel layer 120 and a second width W2 in the length direction of the first spin current channel layer 120. The first and second widths W1 and W2 may be the same as or different from each other. The first spin current channel layer 120 may have a third width W3 in a direction perpendicular to the length direction. The first width W1 of the data storage layer 140 and the third width W3 of the first spin current channel layer 120 may be equal to or different from each other. For example, the first width W1 of the data storage layer 140 may be less than the third width W3 of the first spin current channel layer 120.

The third electrode 130 is disposed in a direction (Y-axis direction) perpendicular or substantially perpendicular to the first spin current channel layer 120. The third electrode 130 may have a fourth width W4 in a direction perpendicular to a length direction (X-axis direction) thereof, and the fourth width W4 may be less or greater than or equal to the second width W2. For example, the third electrode 130 may be formed to cover an entire upper surface of the data storage layer 140.

Although the planar shape of the data storage layer 140 is shown as a rectangle in FIG. 3, it is not limited thereto. In some embodiments, the planar shape of the data storage layer 140 may be circular.

Because a planar shape of the second magnetic memory device 200 may be the same as that of the first magnetic memory device 100, the description of FIG. 3 may be equally applied to the second magnetic memory device 200.

FIG. 4 shows an array 400 of spin orbit torque-magnetoresistive random-access memory (SOT-MRAM) according to an embodiment.

Referring to FIG. 4, the array 400 includes a plurality of first wires 420 arranged in parallel with each other and a plurality of second wires 430 arranged in parallel with each other. The plurality of first wires 420 may be aligned to have a regular interval from each other. The plurality of second wires 430 may be aligned to have a regular interval from each other. The first wire 420 and the second wire 430 may be arranged to cross each other perpendicularly or substantially perpendicularly. A data storage element 4DS is provided at each intersection of the first wire 420 and the second wire 430, that is, at each region where they intersect. One data storage element 4DS and the first and second wires 420 and 430 connected thereto may form a memory cell MC1 that is a minimum memory unit constituting the array 400.

In some embodiments, the first wire 420 may correspond to the first spin current channel layer 120 of the first magnetic memory device 100 or the second spin current channel layer 220 of the second magnetic memory device 200. In some embodiments, the second wire 430 may correspond to the third electrode 130 of the first and second magnetic memory devices 100 and 200.

In some embodiments, the data storage element 4DS may be an MTJ layer and may correspond to the data storage layer 140 of the first and second magnetic memory devices 100 and 200. In some embodiments, the memory cell MC1 may correspond to one of the first and second magnetic memory devices 100 and 200.

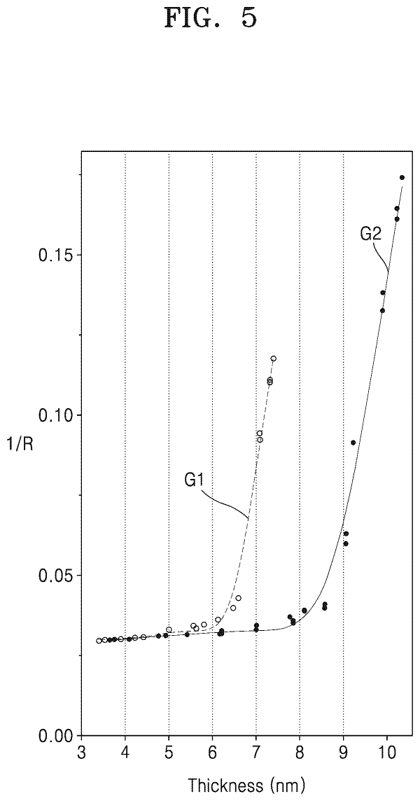

FIG. 5 shows results of a first experiment performed on a magnetic memory device according to an embodiment.

The first experiment was conducted to confirm whether the thickness of the uppermost layers 12B and 22C of the first and second spin current channel layers 120 and 220 of the first and second magnetic memory devices 100 and 200 are as according to the example described above, and the first experiment includes forming a beta-phase W layer on the MgO layer.

In this experiment, an SOT layer and a MTJ layer are sequentially formed. In the process of forming the SOT layer, 1/R of the SOT layer according to the thickness of the SOT layer is measured.

In this experiment, the SOT layer corresponds to the uppermost layers 12B and 22C of the first and second spin current channel layers 120 and 220, and may be a beta-phase W layer formed on the MgO layer.

This experiment was divided into the first experiment and a second experiment.

In the first and second experiments, the W layer was formed as an SOT layer on a layer based on MgO (MgO-based layer). In the first experiment, the W layer was formed under a first condition (400 W, 100 sccm of Ar), and in the second experiment, the W layer was formed under a second condition (80 W, 100 sccm of Ar) different from the first condition. In the first experiment, the W layer was formed to have a thickness of 50 Å (5 nm) (50-wed) at a center of a wafer, and was formed to be less than 5 nm or greater than 5 nm at a location away from the center of the wafer. In the second experiment, the W layer was formed to have a thickness of 70 Å (7 nm) (70-wed) at the center of the wafer, and was formed to be less than 7 nm or greater than 7 nm at a location away from the center of the wafer.

In the first and second experiments, except for the formation conditions of the W layer, the layer composition, material, and formation conditions of the remaining layers were all the same.

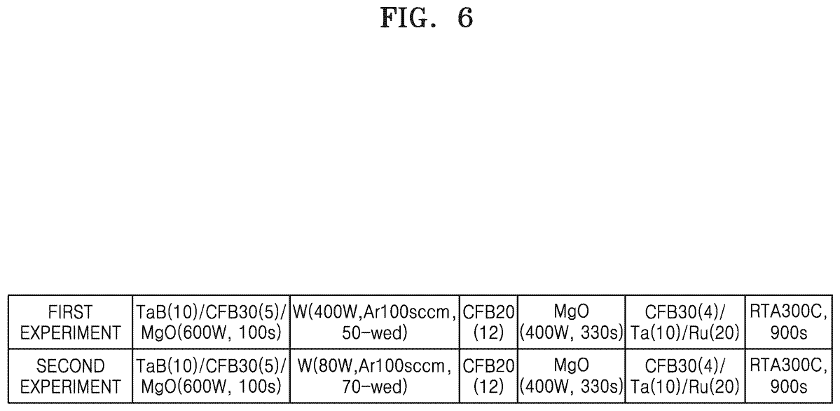

FIG. 6 summarizes the layers formed in the first and second experiments and the formation conditions of each layer.

In FIG. 6, column 2 represents the MgO-based layer.

In the first and second experiments, the MgO-based layer was formed by sequentially stacking a TaB layer, a CFB₃₀ layer, and an MgO layer. The MgO-based layer was formed over 100 seconds at 600 W. The TaB layer was formed to a thickness of about 10 nm, and the CFB₃₀ layer was formed to a thickness of about 5 nm.

In FIG. 6, column 3 represents the first and second conditions of the W layer (SOT layer).

In FIG. 6, CFB20 in column 4 represents the free layer of the MTJ layer. The CFB20 layer was formed to a thickness of about 10 nm.

Column 5 in FIG. 6 represents a barrier layer of the MTJ layer. In the first and second experiments, the barrier layer was formed as a MgO layer, and was formed at 400 W for 330 seconds.

In FIG. 6, column 6 represents a pinned layer of the MTJ layer. In the first and second experiments, the pinned layer was formed by sequentially stacking a CFB30 layer, a Ta layer, and a Ru layer, and each layer was formed to a thickness of about 4 nm, 10 nm, and 20 nm.

Column 7 in FIG. 6, after the MTJ layer is formed, shows an annealing method for a resultant product on which the MTJ layer is formed. In the first and second experiments, the resultant product on which the MTJ layer is formed was annealed at 300° C. for 900 seconds using a rapid thermal anneal (RTA) method.

In FIG. 5, the horizontal axis represents thickness of the W layer, and the vertical axis represents 1/R.

In FIG. 5, a first graph G1 represents the result of the first experiment, and a second graph G2 represents the result of the second experiment.

Referring to the first graph G1 of FIG. 5, the 1/R value maintains a substantially constant value without significant change until the thickness of the W layer reaches about 6 nm. As the thickness of the W layer exceeds 6 nm, the 1/R value increases rapidly. In other words, as the thickness of the W layer exceeds 6 nm in the first experiment, the resistance of the W layer rapidly decreases.

These results suggest that, in the case of the W layer formed according to the first experiment, the beta phase is maintained until the thickness reaches 6 nm, and the phase changes from the beta phase to an alpha phase as the thickness increases to 6 nm or more. This means that a SHA value of the W layer is maintained at about 3 to 5 until the thickness of the W layer is about 6 nm.

In the case of the SOT layer (W layer) formed on the existing SiO₂ layer, considering that the beta phase is maintained up to about 4 nm, the result of the first experiment shows that when the W layer is formed on the MgO-based layer, the W layer in which the beta phase is maintained may be formed greater than before.

Referring to the second graph G2 of FIG. 5, the 1/R value maintains a substantially constant value without significant change until the thickness of the W layer reaches about 8 nm, maximum about 8.5 nm. As the thickness of the W layer exceeds 8.5 nm, the 1/R value increases rapidly. That is, as the thickness of the W layer exceeds 8.5 nm, the resistance of the W layer rapidly decreases.

The results suggest that, in the case of the W layer formed according to the second experiment, the beta phase is maintained until the thickness reaches a maximum of 8.5 nm, and the phase changes from the beta phase to the alpha phase as the thickness becomes greater than the maximum of 8.5 nm. This means that the SHA value of the W layer is maintained at about 3 to about 5 and/or about 3 to about 8 until the thickness of the W layer reaches a maximum of about 8.5 nm.

The results of the second experiment may denote that, similar to the results of the first experiment, when the W layer is formed on the MgO-based layer, the W layer maintaining the beta phase may be formed greater than before.

The thickness of the W layer formed according to the second experiment is greater than that of the W layer formed according to the first experiment. Considering the conditions of the first and second experiments, the result indicates that the thickness of the W layer having a beta phase increases as the power decreases within a power range in which the W layer may be deposited in the same manufacturing process.

As a result, the results of the first experiment shown in FIG. 5 show that the uppermost layers 12B and 22C serving as SOT layers in the spin current channel layers 120 and 220 of the first and second magnetic memory devices 100 and 200 may be formed to the example thickness, and, at this thickness, the phase of a corresponding material layer is maintained as a beta phase.

As the uppermost layers 12B and 22C serving as SOT layers in the spin current channel layers 120 and 220 are formed greater than the existing SOT layer while maintaining a beta (β)-phase, serious side effects, such as damage to the SOT layer or cutting of the SOT layer, which may occur in a subsequent process, for example, an etching process for forming the MTJ layer, may be limited, minimized or prevented. Accordingly, it is possible to limit and/or minimize the number of failed magnetic memory cells, and eventually lead to an increase in yield.

In addition, as the thickness of the uppermost layers 12B and 22C serving as SOT layers become greater than the existing SOT layer, a sufficient margin for limiting and/or preventing damage to the SOT layer in the above etching process is provided. Therefore, the possibility of applying the illustrated manufacturing process of the magnetic memory device to an actual manufacturing process may increase.

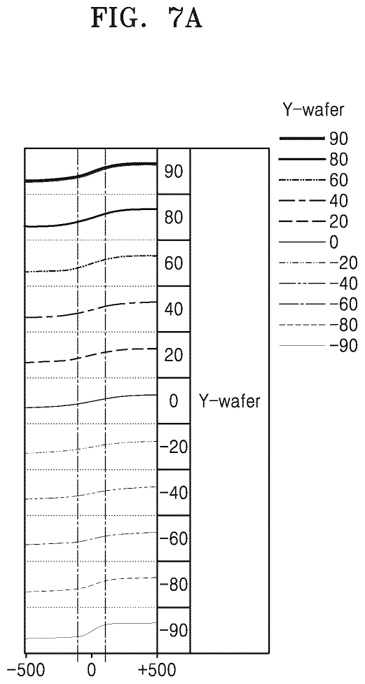

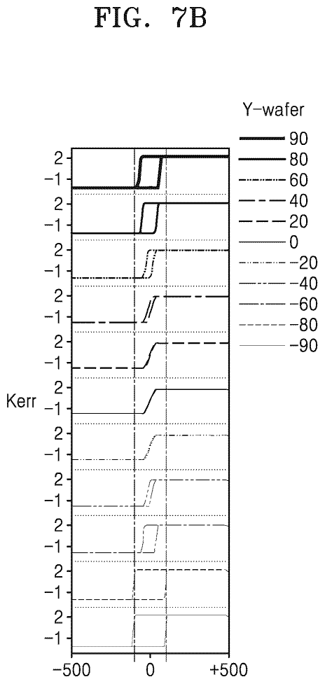

FIGS. 7A and 7B show results of the second experiment performed on a magnetic memory device according to an embodiment.

The second experiment was conducted to confirm the perpendicular magnetic anisotropy of a free layer (e.g., CFB20 layer) formed on the W layer having a beta phase, which is formed greater than before on the MgO-based layer described with reference to FIG. 5. In the experiment, a SOT layer and a MTJ layer are sequentially formed. After the SOT layer was formed, a free layer was formed on the SOT layer, and then the presence or absence of perpendicular magnetic anisotropy with respect to the free layer was confirmed, and magnetic hysteretic characteristics of the free layer were measured for the confirmation.

If the magnetic hysteretic characteristics are measured, it may be determined that the perpendicular magnetic anisotropy is present, and if the magnetic hysteretic characteristics are not measured or the measured value is not significant, it may be determined that the perpendicular magnetic anisotropy is not present.

For this experiment, a magnetic memory device according to an embodiment (hereinafter referred to as a comparison device) and an existing magnetic memory device (hereinafter referred to as a reference device) were prepared.

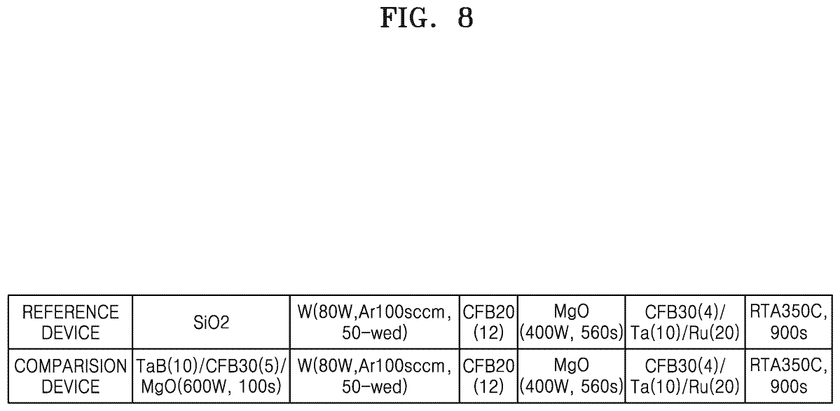

FIG. 8 shows information on a layer structure and a layer configuration of the comparison device and the reference device.

In FIG. 8, column 2 represents a lower layer in which the W layer, which is the SOT layer, is formed. In the case of the comparison device, an MgO-based layer was used as the lower layer, and in the case of the reference device, a SiO₂ layer was used as the lower layer. As the MgO-based layer, a TaB layer, a CFB30 layer, and an MgO layer sequentially stacked were used. This MgO-based layer was formed for 100 seconds at 600W. The figures in parentheses next to each layer constituting the MgO-based layer denotes the thickness of each layer. That is, in the MgO-based layer, the TaB layer was formed to a thickness of about 10 nm and the CFB30 layer to a thickness of about 5 nm. The SiO₂ layer was formed to a thickness corresponding to the thickness of the MgO-based layer.

In FIG. 8, column 3 represents the SOT layer (W layer) formed on the SiO₂ layer and the MgO-based layer. In the comparison and reference devices, the W layer was formed under the same conditions (condition of supplying 100 sccm of Ar at 80 W). “50-wed” indicates that the W layer was formed to have a thickness of about 50 Å at the center of a wafer.

In FIG. 8, column 4 represents the free layer of the MTJ layer. In the comparison and reference devices, the free layer was formed of CFB20 and had a thickness of about 12 nm.

In FIG. 8, column 5 represents a barrier layer of the MTJ layer. In the comparison and reference devices, the barrier layer was formed of an MgO layer and was formed at 400 W for 560 seconds.

In FIG. 8, column 6 represents a pinned layer of the MTJ layer. In the comparison and reference devices, the pinned layer was formed by sequentially stacking a CFB30 layer, a Ta layer, and a Ru layer, and each layer was formed to a thickness of about 4 nm, 10 nm, and 20 nm.

In FIG. 8, column 7 shows, after forming the MTJ layer, an annealing method for a resultant product in which the MTJ layer was formed. In the comparison and reference devices, the MTJ layer was formed and annealed at 350° C. for 900 seconds using an RTA method.

As may be seen in FIG. 8, except that the W layer is formed on the MgO-based layer in the comparison device and the W layer is formed on the SiO₂ layer in the reference device, the other layer configurations and layer structures of the comparison device and the reference device were identical to each other.

Referring to FIGS. 7A and 7B, FIG. 7A shows measurement results of magnetic hysteresis characteristics of the reference device. FIG. 7B shows the measurement results of magnetic hysteresis characteristics of the comparison device.

The magnetic hysteretic characteristics of the comparison and reference devices were measured at several locations (e.g., 11 locations) on the wafer, and the numbers (90, 80 . . . 0 . . . −80, −90) in FIGS. 7A and 7B indicate the position where the magnetic hysteretic characteristics were measured on the wafer. For example, “0” indicates the center of the wafer, and the larger the number, the farther away from the center of the wafer, regardless of + or − signs. + and − signs indicate directions opposite to each other based on the center of the wafer.

In FIG. 7A, no curve showing magnetic hysteretic characteristics may be seen. This suggests that the W layer formed to have the above thickness on the SiO₂ layer in the comparison device does not have perpendicular magnetic anisotropy.

Although there is a difference in degree in FIG. 7B, all curves show magnetic hysteretic characteristics. This suggests that the W layer formed on the MgO-based layer in the comparison device has perpendicular magnetic anisotropy.

Experimental results of FIGS. 7A and 7B suggest that the free layer 14F of the MTJ layer 140 formed on the SOT layers 12B and 22C of the magnetic memory devices 100 and 200 described above may exhibit perpendicular magnetic anisotropy.

Next, electronic apparatus(es) according to an embodiment will be described. The electronic apparatus(es) according to an embodiment may include a magnetic memory device according to an embodiment described above.

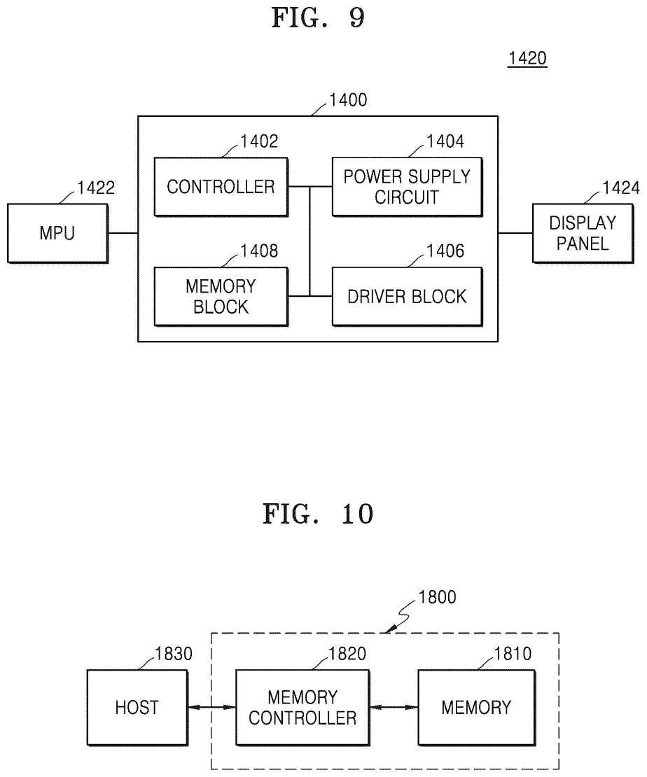

FIG. 9 is a schematic block diagram of a display device 1420 including a display driver IC (DDI) 1400, as a first electronic apparatus according to an embodiment.

Referring to FIG. 9, the DDI 1400 may include a controller 1402, a power supply circuit unit 1404, a driver block 1406, and a memory block 1408. The controller 1402 receives and decodes a command applied from a main processing unit (MPU) 1422 and controls each block of the DDI 1400 to implement an operation according to the command. The power supply circuit 1404 generates a driving voltage in response to the control of the controller 1402. The driver block 1406 drives a display panel 1424 using a driving voltage generated by the power supply circuit unit 1404 in response to the control of the controller 1402. The display panel 1424 may be a liquid crystal display panel or a plasma display panel, but is not limited thereto, and may be a display panel that does not use liquid crystal or plasma. The memory block 1408 is a block that temporarily stores a command input to the controller 1402 or control signals output from the controller 1402 or stores necessary data, and includes a volatile memory (e.g., RAM) and/or a non-volatile memory. In some embodiments, the non-volatile memory may include a ROM or a magnetic memory device illustrated in any one of FIGS. 1 to 4 and/or an array including the same.

FIG. 10 is a block diagram illustrating an electronic system 1800 as a second electronic apparatus according to an embodiment.

Referring to FIG. 10, the electronic system 1800 includes a memory 1810 and a memory controller 1820. The memory controller 1820 may control the memory 1810 to read data from and/or write data to the memory 1810 in response to a request from the host 1830. In some embodiments, the memory 1810 may include the magnetic memory device illustrated in any one of FIGS. 1 to 4 and/or an array including the magnetic memory device.

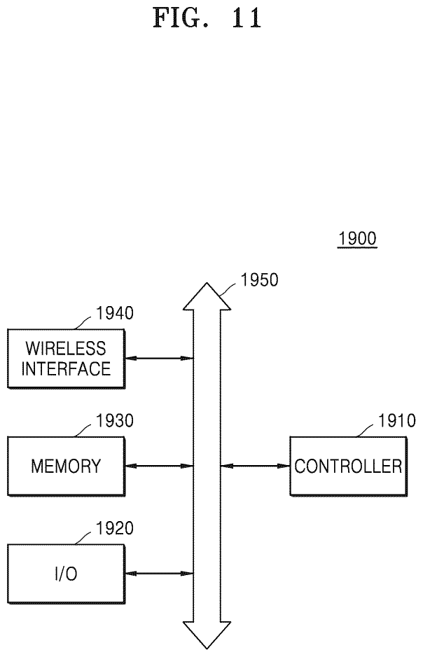

FIG. 11 is a block diagram of an electronic system 1900 as a third electronic apparatus according to an embodiment.

Referring to FIG. 11, the electronic system 1900 may be a wireless communication device or a device capable of transmitting and/or receiving information in a wireless environment. The electronic system 1900 includes a controller 1910, an input/output (I/O) device 1920, a memory 1930, and a wireless interface 1940, and these components are interconnected to each other through a bus 1950.

The controller 1910 may include at least one of a microprocessor, a digital signal processor, and a processing device similar thereto. The I/O device 1920 may include at least one of a keypad, a keyboard, and a display.

The memory 1930 may be used to store instructions executed by the controller 1910. For example, the memory 1930 may be used to store user data. In some embodiments, the memory 1930 may include the magnetic memory device illustrated in any one of FIGS. 1 to 4 and/or an array including the magnetic memory device.

The electronic system 1900 may use the wireless interface 1940 to transmit/receive data over a wireless communication network. The wireless interface 1940 may include an antenna and/or a wireless transceiver. In some embodiments, the electronic system 1900 may be used in a communication interface protocol of a third-generation communication system, for example, code division multiple access (CDMA), global system for mobile communications (GSM), north American digital cellular (NADC), extended-time division multiple access (E-TDMA), and/or wide band code division multiple access (WCDMA).

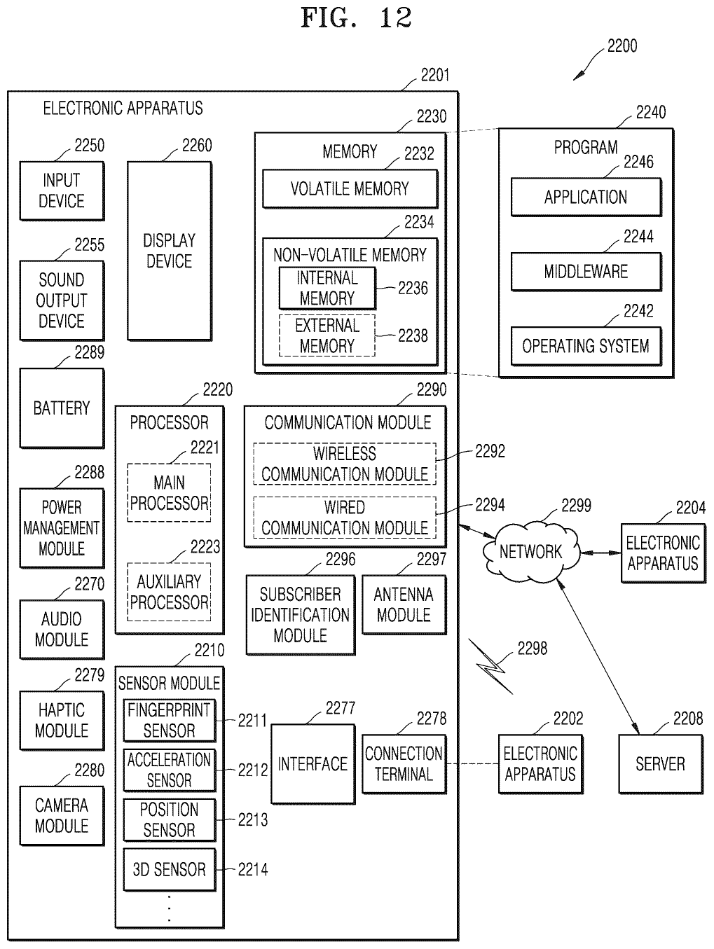

FIG. 12 is a block diagram showing a schematic configuration of a fourth electronic apparatus according to an embodiment.

Referring to FIG. 12, in a network environment 2200, an electronic apparatus 2201 may communicate with another electronic apparatus 2202 through a first network 2298 (e.g., a short-range wireless communication network, etc.) or may communicate with another electronic apparatus 2204 and/or a server 2208 through a second network 2299 (e.g., a remote wireless communication network). The electronic apparatus 2201 may communicate with the electronic apparatus 2204 through the server 2208. The electronic apparatus 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. In the electronic apparatus 2201, some of these components (e.g., the display device 2260) may be omitted or other components may be added. Some of these components may be implemented as one integrated circuit. For example, a fingerprint sensor 2211 of the sensor module 2210, an iris sensor, an illuminance sensor, etc. may be implemented in a form embedded in the display device 2260 (a display, etc.).

The processor 2220 may execute software (such as a program 2240) to control one or a plurality of other components (hardware, software components, etc.) of the electronic apparatus 2201 connected to the processor 2220, and may perform various data processing or operations. As part of data processing or operations, the processor 2220 may load commands and/or data received from other components (the sensor module 2210, the communication module 2290, etc.) into a volatile memory 2232, and may process commands and/or data stored in the volatile memory 2232, and store resulting data in a non-volatile memory 2234. The processor 2220 may include a main processor 2221 (a central processing unit, an application processor, etc.) and an auxiliary processor 2223 (a graphics processing unit, an image signal processor, a sensor hub processor, a communication processor, etc.) that may be operated independently or together with the main processor 2221. The auxiliary processor 2223 may use less power than the main processor 2221 and may perform a specialized function.

The auxiliary processor 2223 may control functions and/or states related to some of the components (e.g., the display device 2260, the sensor module 2210, the communication module 2290) of the electronic apparatus 2201 instead of the main processor 2221 while the main processor 2221 is in an inactive state (sleep state), or together with the main processor 2221 while the main processor 2221 is in an active state (application execution state). The auxiliary processor 2223 (an image signal processor, a communication processor, etc.) may be implemented as a part of other functionally related components (the camera module 2280, the communication module 2290, etc.).

The memory 2230 may store various data required by components of the electronic apparatus 2201 (the processor 2220, the sensor module 2276, etc.). The data may include, for example, input data and/or output data for software (such as the program 2240) and instructions related to the command. The memory 2230 may include a volatile memory 2232 and/or a non-volatile memory 2234. The non-volatile memory 2234 may include an internal memory 2236 and an external memory 2238. In some embodiments, the non-volatile memory 2234 may include the magnetic memory device illustrated in any one of FIGS. 1 to 4 and/or an array including the magnetic memory device.

The program 2240 may be stored as software in the memory 2230, and may include an operating system 2242, middleware 2244, and/or an application 2246.

The input device 2250 may receive commands and/or data to be used in a component (e.g., the processor 2220) of the electronic apparatus 2201 from the outside of the electronic apparatus 2201 (e.g., a user). The input device 2250 may include a microphone, a mouse, a keyboard, and/or a digital pen (such as a stylus pen).

The sound output device 2255 may output a sound signal to the outside of the electronic device 2201. The sound output device 2255 may include a speaker and/or a receiver. The speaker may be used for general purposes, such as multimedia playback or recording playback, and the receiver may be used to receive incoming calls. The receiver may be integrated as a part of the speaker or may be implemented as an independent separate device.

The display device 2260 may visually provide information to the outside of the electronic device 2201. The display device 2260 may include a control circuit for controlling a display, a hologram device, or a projector and a corresponding device. The display device 2260 may include a touch circuitry configured to sense a touch, and/or a sensor circuitry configured to measure the intensity of force generated by the touch (e.g., a pressure sensor, etc.).

The audio module 2270 may convert a sound into an electric signal or, conversely, convert an electric signal into a sound. The audio module 2270 may obtain a sound through the input device 2250 or may output a sound through a speaker and/or headphone of the sound output device 2255 and/or another electronic apparatus (e.g., the electronic apparatus 2202) directly or wirelessly connected to electronic apparatus 2201.

The sensor module 2210 may detect an operating state (power, temperature, etc.) of the electronic apparatus 2201 or an external environmental state (user state, etc.), and may generate an electrical signal and/or data value corresponding to the sensed state. The sensor module 2210 may include a fingerprint sensor 2211, an acceleration sensor 2212, a position sensor 2213, a 3D sensor 2214, and the like, and in addition to the above sensors, may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The 3D sensor 2214 may sense a shape and movement of an object by irradiating a desired and/or alternatively predetermined light to the object and analyzing light reflected from the object, and may include a meta-optical device.

The interface 2277 may support one or more designated protocols that may be used by the electronic apparatus 2201 to connect directly or wirelessly with another electronic apparatus (e.g., the electronic device 2102). The interface 2277 may include a High Definition Multimedia Interface (HDMI), a Universal Serial Bus (USB) interface, an SD card interface, and/or an audio interface.

The connection terminal 2278 may include a connector through which the electronic apparatus 2201 may be physically connected to another electronic apparatus (e.g., the electronic apparatus 2202). The connection terminal 2278 may include an HDMI connector, a USB connector, an SD card connector, and/or an audio connector (e.g., a headphone connector).

The haptic module 2279 may convert an electrical signal into a mechanical stimulus (vibration, movement, etc.) or an electrical stimulus that the user may perceive through tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly included in the camera module 2280 may collect light emitted from an object, which is an imaging target.

The power management module 2288 may manage power supplied to the electronic apparatus 2201. The power management module 2288 may be implemented as part of a Power Management Integrated Circuit (PMIC).

The battery 2289 may supply power to components of the electronic apparatus 2201. The battery 2289 may include a non-rechargeable primary cell, a rechargeable secondary cell, and/or a fuel cell.

The communication module 2290 establishes a direct (wired) communication channel and/or wireless communication channel between the electronic apparatus 2201 and other electronic apparatuses (the electronic apparatus 2202, an electronic apparatus 2204, server 2208, etc.) and performing communication through an established communication channel. The communication module 2290 may include one or more communication processors that operate independently of the processor 2220 (e.g., an application processor) and support direct communication and/or wireless communication. The communication module 2290 may include a wireless communication module 2292 (a cellular communication module, a short-range wireless communication module, a Global Navigation Satellite System (GNSS, etc.) communication module) and/or a wired communication module 2294 (a Local Area Network (LAN) communication module, or a power line communication module, etc.). Among these communication modules, a corresponding communication module may communicate with other electronic apparatuses through the first network 2298 (a short-range communication network, such as Bluetooth, WiFi Direct, or Infrared Data Association (IrDA)) or the second network 2299 (a telecommunication network, such as a cellular network, the Internet, or a computer network (LAN) and WAN, etc.). The various types of communication modules may be integrated into one component (a single chip, etc.) or implemented as a plurality of components (plural chips) separate from each other. The wireless communication module 2292 may identify and authenticate the electronic apparatus 2201 within a communication network, such as the first network 2298 and/or the second network 2299 by using subscriber information (such as, International Mobile Subscriber Identifier (IMSI)) stored in a subscriber identification module 2296.

The antenna module 2297 may transmit or receive signals and/or power to and from the outside (other electronic apparatuses, etc.). The antenna may include a radiator having a conductive pattern formed on a substrate (PCB, etc.). The antenna module 2297 may include one or a plurality of antennas. When a plurality of antennas is included in the antenna module 2297, an antenna suitable for a communication method used in a communication network, such as the first network 2298 and/or the second network 2299 from among the plurality of antennas may be selected by the communication module 2290. Signals and/or power may be transmitted or received between the communication module 2290 and another electronic apparatus through the selected antenna. In addition to the antenna, other components (an RFIC, etc.) may be included as a part of the antenna module 2297.

Some of the components are connected to each other through a communication method between peripheral devices (a bus, a General Purpose Input and Output (GPIO), a Serial Peripheral Interface (SPI), a Mobile Industry Processor Interface (MIPI), etc.), and may interchange signals (commands, data, etc.).

The command or data may be transmitted or received between the electronic apparatus 2201 and the external electronic apparatus 2204 through the server 2208 connected to the second network 2299. The other electronic apparatuses 2202 and 2204 may be the same or different types of electronic apparatus 2201. All or some of operations performed in the electronic apparatus 2201 may be performed in one or more of the other electronic apparatuses 2202, 2204, and 2208. For example, when the electronic apparatus 2201 needs to perform a function or service, the electronic apparatus 2201 may request one or more other electronic apparatuses to perform part or all function or service instead of executing the function or service itself. One or more other electronic apparatuses receiving the request may execute an additional function or service related to the request, and transmit a result of the execution to the electronic apparatus 2201. For this purpose, cloud computing, distributed computing, and/or client-server computing technologies may be used.

Any or all of the elements described with reference to FIG. 12 may communicate with any or all other elements described with reference to FIG. 12. For example, any element may engage in one-way and/or two-way and/or broadcast communication with any or all other elements in FIG. 12, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

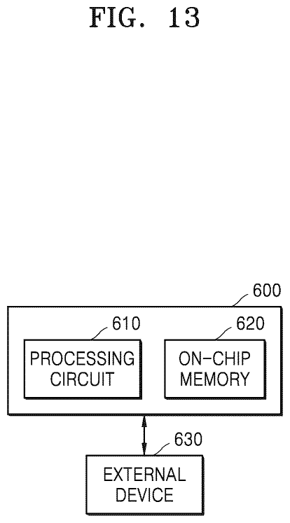

FIG. 13 is a diagram schematically illustrating a fifth electronic apparatus according to an embodiment.

Referring to FIG. 13, the electronic apparatus 600 may include a processing circuit 610 and an on-chip memory 620.

The processing circuit 610 may be configured to control functions for driving the electronic apparatus 600. For example, the processing circuit 610 may control the electronic apparatus 600 by executing a program stored in the on-chip memory 620 of the electronic apparatus 600.

The processing circuit 610 may include hardware, such as logic circuitry, a combination of hardware and software, such as a processor that executes software, or a combination thereof.

Also, the processing circuit 610 may read and write various data from an external device 630 and execute the electronic apparatus 600 using the data. The external device 630 may include an external memory device and/or a sensor array including an image sensor (e.g., a CMOS image sensor circuit).

The on-chip memory 620 may include the magnetic memory device illustrated in any one of FIGS. 1 to 4 and/or an array including the magnetic memory device.

The magnetic memory device using the disclosed spin current has a layer structure in which an MgO layer and a tungsten (W) layer having a beta phase are sequentially stacked under an MTJ layer. The thickness of the beta-phase tungsten layer (SOT layer) formed on the MgO layer is greater than that of the beta-phase tungsten layer formed on the existing SiO₂ layer. Therefore, in the case of the SOT-MRAM including the disclosed magnetic memory device, the following advantages may be added while maintaining the advantages of the existing SOT-MRAM.

That is, because the thickness of the beta-phase tungsten layer (SOT layer) is greater than before, it is possible to prevent side effects in which the SOT layer is severely damaged or cut in a process for forming the MTJ layer (e.g., an etching process). In this way, the failure of the magnetic memory device may minimize and consequently the yield of the magnetic memory device may be increased.

In addition, as the thickness of the beta-phase tungsten layer increases, the perpendicular magnetic anisotropy of the free layer of the MTJ layer formed thereon may be enhanced, and accordingly, the data non-volatile state may be accurately maintained for a longer period of time.

In addition, in the case of the beta-phase tungsten layer, because the SHA value is greater than that of the alpha-phase tungsten layer, the operating current density of the SOT-MRAM including the disclosed magnetic memory device may be reduced.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A magnetic memory device comprising:
a spin current channel layer;
a wiring crossing the spin current channel layer; and
a magnetic tunnel junction (MTJ) layer at an intersection of the spin current channel layer with the wiring, wherein
the spin current channel layer includes a MgO-based layer and a beta-phase tungsten layer on the MgO-based layer, and
the beta-phase tungsten layer is in contact with the MTJ layer.

2. The magnetic memory device of claim 1, wherein the MgO-based layer is a single layer including an MgO layer.

3. The magnetic memory device of claim 1, wherein
the MgO-based layer includes a first layer and a second layer on the first layer, and
the second layer is in contact with the beta-phase tungsten layer.

4. The magnetic memory device of claim 3, wherein the second layer includes an MgO layer.

5. The magnetic memory device of claim 3, wherein the first layer is a single layer including a metal of one component.

6. The magnetic memory device of claim 3, wherein
the first layer includes a two-component material layer, and
the two-component material layer includes a metal component and a non-metal component.

7. The magnetic memory device of claim 6, wherein the two-component material layer includes one of a metal oxide and a metal nitride.

8. The magnetic memory device of claim 3, wherein the first layer includes an alloy.

9. The magnetic memory device of claim 3, wherein
the first layer includes a three-component material layer, and
the three-component material layer includes two different metals and one non-metal component.

10. The magnetic memory device of claim 3, wherein
the first layer includes a first material layer and a second material layer on the first material layer.

11. The magnetic memory device of claim 10, wherein
the first material layer includes one of Ta and TaB, and
the second material layer includes CoFeB.

12. The magnetic memory device of claim 1, wherein a thickness of the beta-phase tungsten layer is in a range from about 5.5 nm to about 8.0 nm.

13. The magnetic memory device of claim 1, further comprising:
a plurality of the spin current channel layers spaced apart from each other;
a plurality of the wirings spaced apart from each other; and
a plurality of the MTJ layers at intersections of the plurality of spin current channel layers with the plurality of wirings.

14. A magnetic memory device comprising:
a spin current channel layer;
a wiring crossing the spin current channel layer; and
an MTJ layer at an intersection of the spin current channel layer with the wiring, wherein
the spin current channel layer includes a first layer and a second layer on the first layer,
the first layer includes a metal, and
the second layer has a spin hall angle (SHA) in a range from about 0.3 to about 0.5.

15. The magnetic memory device of claim 14, wherein the first layer includes a TaN layer.

16. The magnetic memory device of claim 14, wherein the first layer includes an NiO layer.

17. The magnetic memory device of claim 14, further comprising:
a first material layer contacting the first layer, wherein
the first layer includes one of a TaN layer and an NiO layer.

18. The magnetic memory device of claim 17, wherein the first material layer includes at least one of a single-layer metal layer, an alloy layer, and a three-component material layer.

19. The magnetic memory device of claim 14, further comprising:
a plurality of the spin current channel layers spaced apart from each other;
a plurality of the wirings spaced apart from each other; and
a plurality of the MTJ layers at intersections of the plurality of spin current channel layers with the plurality of wirings.

20. An electronic apparatus comprising:
the magnetic memory device of claim 1.
